(19) United States
(12) Patent Application Publication
(10) Pub. No.: US 2022/0239545 A1
(43) Pub. Date: Jul. 28, 2022

(54) COMMUNICATION APPARATUS AND COMMUNICATION METHOD

(71) Applicant: TOSHIBA TEC KABUSHIKI KAISHA, Tokyo (JP)

(72) Inventors: Sunao Tsuchida, Mishima Shizuoka (JP); Sadatoshi Oishi, Fuji Shizuoka (JP)

(21) Appl. No.: 17/510,421

(22) Filed: Oct. 26, 2021

(30) Foreign Application Priority Data
Jan. 22, 2021 (JP) 2021-008805

(51) Int. Cl. H04L 27/36; H03F 3/24; H04L 27/00

(52) U.S. Cl. CPC H04L 27/364; H03F 3/24; H03F 2200/451; H04L 27/366; H04L 2027/0016; H04L 27/0014

(57) ABSTRACT

A quadrature modulator and the transmission unit output a modulated wave obtained by performing quadrature modulation on a carrier wave using a first I signal and a first Q signal and wirelessly transmit the modulated wave. A reception unit and the quadrature detector detect a received signal corresponding to a wireless signal transmitted from the wireless tag using the carrier wave and to output a second I signal and a second Q signal. A filter and the amplification unit amplify a frequency component higher than a cutoff frequency in the second I signal and the second Q signal. A detector and the decoding unit decode data based on a detection signal obtained by detecting the amplified second I signal and the amplified second Q signal. A generation unit generates the first I signal and the first Q signal such that the modulated wave is a signal obtained by shifting a frequency of the carrier wave by a frequency shift amount more than the cutoff frequency and to input the first I signal and the first Q signal to the quadrature modulator.

### CROSS-REFERENCE TO RELATED APPLICATION

This application is based upon and claims the benefit of priority from Japanese Patent Application No. 2021-008805, filed on Jan. 22, 2021, the entire contents of which are incorporated herein by reference.

### FIELD

Embodiments described herein relate generally to a communication apparatus and a communication method.

### BACKGROUND

A communication apparatus that receives a reflected wave from a wireless tag using a backscattering method and demodulates transmitted data from the wireless tag is known.

In this communication apparatus, a variable gain amplifier (VGA) is used to amplify the demodulated signal. In addition, in order to prevent the demodulated signal from being saturated by amplification, a high pass filter (HPF) is used.

However, if the bit rate of the transmitted data from the wireless tag is low at, for example, about 1 kbps and the frequency of the demodulated signal is low, the demodulated signal is blocked by the HPF. If a direct current (DC) cut capacitor is used as the HPF, the DC cut capacitor can allow transmission of the demodulated signal by increasing the capacitance of the demodulated signal. However, there is a problem in that the signal waveform is distorted due to transient response.

### DESCRIPTION OF THE DRAWINGS

FIG. 1 is a block diagram illustrating a main circuit configuration of a reading apparatus according to one embodiment;

FIG. 2 is a diagram illustrating waveforms of various signals;

FIG. 3 is a diagram illustrating waveforms of a received I signal and a received Q signal;

FIG. 4 is a diagram illustrating waveforms of various signals according to a modification example; and

FIG. 5 is a diagram illustrating waveforms of a received I signal and a received Q signal.

### DETAILED DESCRIPTION

Embodiments provide a communication apparatus and a communication method capable of appropriately decoding transmitted data having a low transmission rate from a received signal. The communication apparatus and a communication method enable transmitted data having a low transmission rate to be appropriately decoded from a received signal.

In general, according to one embodiment, a communication apparatus includes a quadrature modulator, a transmission unit, a reception unit, a quadrature detector, a filter unit, an amplification unit, a detection unit, a decoding unit, and a generation unit. The quadrature modulator is configured to output a modulated wave obtained by performing quadrature modulation on a carrier wave using a first I signal and a first Q signal. The transmission unit is configured to wirelessly transmit the modulated wave output from the quadrature modulator. The reception unit is configured to receive a wireless signal obtained if the transmitted wave from the transmission unit is backscattered by the wireless tag and undergoes amplitude shift keying. The quadrature detector is configured to detect the received signal received by the reception unit using the carrier wave and to output a second I signal and a second Q signal. The filter unit is configured to allow transmission of a frequency component higher than a cutoff frequency in the second I signal and the second Q signal. The amplification unit is configured to amplify the second I signal and the second Q signal transmitted through the filter unit. The detection unit is configured to detect at least one of the second I signal and the second Q signal that are amplified by the amplification unit and to output a detection signal. The decoding unit is configured to decode data transmitted from the wireless tag based on the detection signal output from the detection unit. The generation unit is configured to generate the first I signal and the first Q signal such that the modulated wave is a signal obtained by shifting a frequency of the carrier wave by a frequency shift amount more than the cutoff frequency and to input the first I signal and the first Q signal to the quadrature modulator.

Hereinafter, an example of an embodiment will be described using the drawings. Hereinafter, a reading apparatus that reads data stored in a radio frequency identification (RFID) tag will be described as an example.

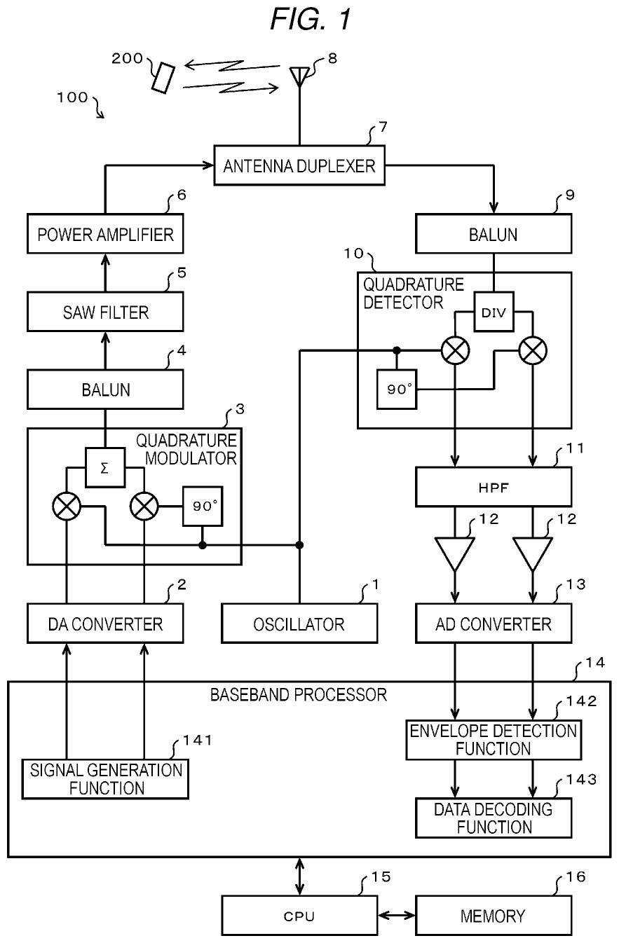

FIG. 1 is a block diagram illustrating a main circuit configuration of a reading apparatus 100 according to the embodiment.

The reading apparatus 100 reads data stored in a RFID tag 200 from the RFID tag 200 using backscatter communication. That is, the reading apparatus 100 wirelessly communicates with the RFID tag 200 if the data is read from the RFID tag 200, and is an example of the communication apparatus.

The reading apparatus 100 includes an oscillator 1, a digital to analog (DA) converter 2, a quadrature modulator 3, a balun 4, a surface acoustic wave (SAW) filter 5, a power amplifier 6, an antenna duplexer 7, an antenna 8, a balun 9, a quadrature detector 10, a HPF 11, two VGAs 12, an analog to digital (AD) converter 13, a baseband processor 14, a central processing unit (CPU) 15, and a memory 16.

The oscillator 1 generates a sine wave of a predetermined frequency f_{local} as a carrier wave.

The DA converter 2 converts each of two-system signals (hereinafter referred to as “transmitted I signal” and “transmitted Q signal”) output from the baseband processor 14 in a digital format into an analog signal.

The transmitted I signal and the transmitted Q signal as the analog signals converted by the DA converter 2 are input to the quadrature modulator 3 as modulated signals. The carrier wave generated by the oscillator 1 and a carrier wave obtained by shifting a phase of the carrier wave by 90° are input to the quadrature modulator 3 as an I-system carrier wave and a Q-system carrier wave, respectively. The quadrature modulator 3 obtains a transmitted signal by quadrature modulation. In the embodiment, as the quadrature modulator 3, a device having a well-known configuration including a phase shifter, two mixers, and an adder is used. However, another well-known device having a different configuration may be used. For example, the quadrature modulator 3 may not include a phase shifter, and a carrier wave obtained by shifting a phase of the carrier wave output from the oscillator 1 by 90° with a phase shifter provided outside the quadrature modulator 3 may be input to the quadrature modulator 3 separately from the carrier wave output from the oscillator 1. The transmitted I signal and the transmitted Q signal correspond to the first I signal and the first Q signal.

The balun 4 converts a balanced signal output from the quadrature modulator 3 into an unbalanced signal.

The SAW filter 5 removes a low-frequency component and a high-frequency component from the transmitted signal output from the balun 4 in order to limit unwanted emission.

The power amplifier 6 amplifies the transmitted signal transmitted through the SAW filter 5 up to a level suitable for wireless transmission.

The antenna duplexer 7 supplies the transmitted signal output from the power amplifier 6 to the antenna 8. The antenna duplexer 7 outputs the received signal received by the antenna 8 to the balun 9.

The antenna 8 emits a radio wave corresponding to the transmitted signal supplied through the antenna duplexer 7. The antenna 8 receives the arrived radio wave. That is, if reflected wave from the RFID tag 200 arrives at the antenna 8, the antenna 8 receives a signal corresponding to the reflected wave.

As described above, the transmitted signal is wirelessly transmitted by the SAW filter 5, the power amplifier 6, and the antenna 8. That is, the SAW filter 5, the power amplifier 6, and the antenna 8 configure a transmission unit that wirelessly transmits modulated wave output from the quadrature modulator 3 as a modulation unit. In addition, the antenna 8 functions as a reception unit that receives a signal corresponding to reflected wave as an amplitude shift keying (ASK) wave transmitted from the RFID tag 200 as an example of the wireless tag using a backscattering method.

The balun 9 converts the unbalanced signal input through the antenna duplexer 7 into a balanced signal.

The quadrature detector 10 detects the received signal output from the balun 9 by quadrature detection using the carrier wave generated by the oscillator 1 and the carrier wave obtained by shifting a phase of the carrier wave by 90°. The quadrature detector 10 outputs the two-system demodulated signals (hereinafter referred to as “received I signal” and “received Q signal”) obtained by the quadrature detection in parallel. In the embodiment, as the quadrature detector 10, a device having a well-known configuration including a distributor, a phase shifter, and two mixers is used. However, another well-known device having a different configuration may be used. For example, the quadrature detector 10 may not include a phase shifter, and a carrier wave obtained by shifting a phase of the carrier wave output from the oscillator 1 by 90° with a phase shifter provided outside the quadrature modulator 3 may be input to the quadrature detector 10 separately from the carrier wave output from the oscillator 1. The received I signal and the received Q signal correspond to the second I signal and the second Q signal.

The HPF 11 allows transmission of a frequency component higher than a predetermined cutoff frequency f_{cut} in each of the received I signal and the received Q signal output from the quadrature detector 10. The HPF 11 includes, for example, two DC cut capacitors corresponding to the received I signal and the received Q signal. The HPF 11 corresponds to the filter unit.

The two VGAs 12 amplify the received I signal and the received Q signal transmitted through the HPF 11 up to levels suitable for envelope detection and data decoding described below. The two VGAs configure the amplification unit.

The AD converter 13 converts each of the received I signal and the received Q signal amplified by the VGAs 12 into a digital signal.

The baseband processor 14 executes information processing for signal processing relating to a baseband signal. The baseband processor 14 has, as functions implemented by executing the information processing, a signal generation function 141, an envelope detection function 142, and a data decoding function 143. The signal generation function 141 is instructed by the CPU 15 to generate the transmitted I signal and the transmitted Q signal for obtaining a predetermined transmitted signal as the output of the quadrature modulator 3 and to input the transmitted I signal and the transmitted Q signal to the DA converter 2 in parallel. The envelope detection function 142 detects each of the received I signal and the received Q signal output from the AD converter 13 by envelop detection. The data decoding function 143 decodes data transmitted from the RFID tag 200 based on the envelop detection result relating to each of the received I signal and the received Q signal.

Thus, the baseband processor 14 functions as the generation unit by the signal generation function 141, functions as a second detection unit by the envelope detection function 142, and functions as the decoding unit by the data decoding function 143.

The CPU 15 controls the baseband processor 14 to output the transmitted I signal and the transmitted Q signal in accordance with a predetermined sequence during communication with the RFID tag 200. The CPU 15 executes predetermined data processing on data reconstructed by the baseband processor 14.

The memory 16 stores an information processing program describing the information processing executed by the CPU 15. The memory 16 stores various types of data required for the CPU 15 to execute various types of information processing. The memory 16 stores various types of data generated or acquired if the CPU 15 executes various types of information processing.

Next, an operation of the reading apparatus 100 configured as described above will be described.

The operation of the reading apparatus 100 is different from that of a well-known reading apparatus in an operation regarding a period in which data is received from the RFID tag 200 regarding communication with the RFID tag 200. Hereinafter, this operation will be described in detail, and description of other well-known operations will not be made.

At a timing at which data reading from the RFID tag 200 should start, the CPU 15 instructs the baseband processor 14 to start reading the data. In accordance with the instruction, the baseband processor 14 starts generating and outputting the transmitted I signal and the transmitted Q signal by the signal generation function 141 such that the transmitted signal output from the quadrature modulator 3 is a desired modulated wave.

The baseband processor 14 generates the transmitted I signal and the transmitted Q signal as modulated signals such that a transmitted signal obtained by performing frequency shift keying (FSK) on a carrier wave having a frequency f_{local} output from the oscillator 1 is output from the quadrature modulator 3. Specifically, the baseband processor 14 generates the transmitted I signal and the transmitted Q signal such that a signal in which a unit period having a frequency of f_{local}+f_{dev} and a unit period having a frequency of f_{local}−f_{dev} are generated in a predetermined pattern is generated as a transmitted signal. The baseband processor 14 sets both of the frequencies of the transmitted I signal and the transmitted Q signal to f_{dev}. By making a phase difference between the transmitted I signal and the transmitted Q signal, the frequency of the carrier wave is shifted by +f_{dev} or −f_{dev} The frequency f_{dev} may be freely determined by, for example, a designer of the reading apparatus 100. In this case, the frequency f_{dev} f is higher than the frequency f_{cut}.

The pattern of the transmitted signal may be freely determined by, for example, the designer of the reading apparatus 100. If the unit period having a frequency of f_{local}+f_{dev} is represented by a first period and the unit period having a frequency of f_{local}−f_{dev} is represented by a second period, a pattern where the first period, the second period, the first period, the first period, the second period, the first period, the second period, and the first period as one cycle are repeated is set. That is, assuming that the frequency f_{local}+f_{dev} is “1” and the frequency of f_{local}−f_{dev} is “0”, a signal obtained by performing FSK on the carrier wave output from the oscillator 1 with data in which the pattern of “1”, “0”, “1”, “1”, “0”, “1”, “0”, and “1” is repeated is generated as a transmitted signal.

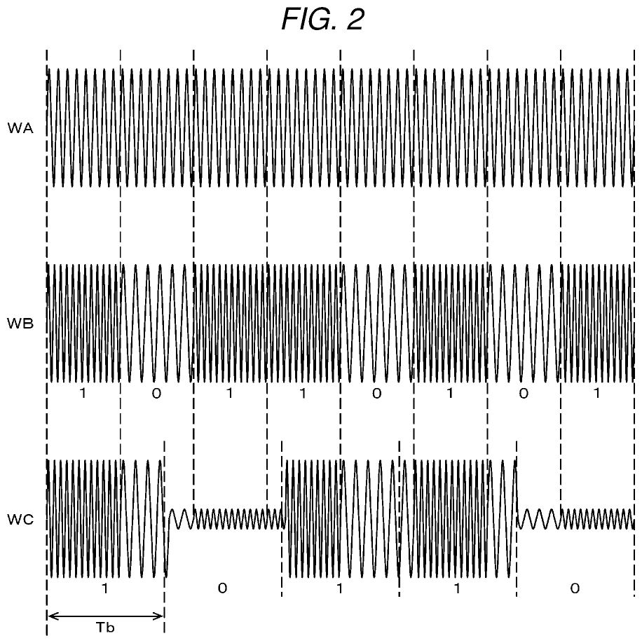

FIG. 2 is a diagram illustrating waveforms of various signals.

A waveform WA on the upper side of FIG. 2 is a waveform of the carrier wave output from the oscillator 1. A waveform WB in the middle of FIG. 2 is a waveform of the above-described signal obtained by performing FSK. A waveform WC on the lower side of FIG. 2 is a waveform of the reflected wave from the RFID tag 200. In this case, FIG. 2 illustrates an image representing an increase in frequency in each of the signals, in which a relationship between the frequency of the waveforms WA and the frequencies of the waveforms WB and WC does not appropriately represent an actual relationship between the frequencies.

If the RFID tag 200 receives the transmitted signal from the reading apparatus 100, the reflectivity thereof changes depending on data to be read by the reading apparatus 100. As a result, the reflected wave from the RFID tag 200 has the waveform WC obtained by performing ASK on the transmitted signal from the reading apparatus 100. One bit period in the reflected wave from the RFID tag 200 is represented by Tb, and a relationship of f_{dev}>1/Tb is satisfied. If the transmission bit rate of the RFID tag 200 is slow, f_{dev}>1/Tb is satisfied, and a relationship of f_{dev}>f_{cut}>1/Tb is satisfied.

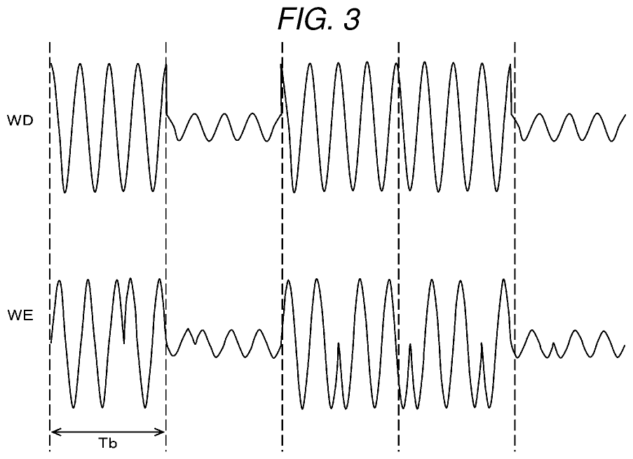

FIG. 3 is a diagram illustrating waveforms of the received I signal and the received Q signal detected by the quadrature detector 10.

If the received signal having the waveform WC on the lower side of FIG. 2 is detected by the quadrature detector 10 by quadrature detection, the received I signal having a waveform WD on the upper side of FIG. 3 and the received Q signal having a waveform WE on the lower side of FIG. 3 are obtained.

The frequencies of the received I signal and the received Q signal are f_{dev} and are higher than the cutoff frequency f_{cut} in the HPF 11. Therefore, the received I signal and the received Q signal transmit through the HPF 11.

In the baseband processor 14, if the received I signal and the received Q signal as digital signals that are transmitted through the HPF 11, amplified by the VGAs 12, and are converted by the AD converter 13 are input, envelop detection is performed on the received I signal and the received Q signal by the envelope detection function 142. As a result, two-system baseband signals corresponding to the transmitted data of the RFID tag 200 from which the component of the frequency f_{dev} is removed can be obtained. The baseband processor 14 decodes the transmitted data of the RFID tag 200 by the data decoding function 143 with respect to the result of the envelop detection. The envelope detection function 142 may extract the baseband signal by performing quadrature detection in digital signal processing instead of envelop detection. In addition, the processing for decoding may be performed, for example, using the same method as that of another existing reading apparatus.

As described above, with the reading apparatus 100, even if the transmission bit rate of the RFID tag 200 is slow, the signal can be amplified by the VGA 12 without being blocked by the HPF 11, and the transmitted data from the RFID tag 200 can be appropriately decoded.

The reading apparatus 100 implements FSK using the quadrature modulator 3. Therefore, by changing the processing in the baseband processor 14, FSK can be implemented without changing the hardware configuration.

This embodiment can be modified as follows in various ways.

In the above-described embodiment, the data used for FSK is the data in which the pattern of “1”, “0”, “1”, “1”, “0”, “1”, “0”, and “1” is repeated. However, the data used for FSK is not particularly limited. For example, the data used for FSK may be data in which “0” or “1” is randomly generated. For example, a pattern may be predetermined until the reception of the transmitted data of the RFID tag 200 is completed. Further, the data used for FSK may be data in which “0” or “1” is continuous.

Assuming that the data used for FSK is data in which “0” or “1” is continuous, the baseband processor 14 only has to continuously output the transmitted I signal and the transmitted Q signal having a predetermined phase relationship.

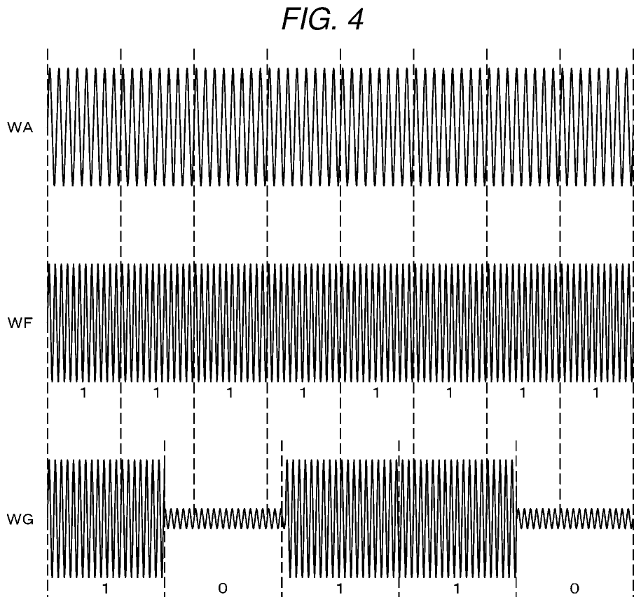

FIG. 4 is a diagram illustrating waveforms of transmitted signals if data in which “1” is continuous is used for FSK.

The waveform WA on the upper side of FIG. 4 is the waveform of the carrier wave output from the oscillator 1 and is the same as that illustrated in FIG. 2. A waveform WF in the middle of FIG. 4 is a waveform of a signal obtained by performing FSK on the carrier wave with the data in which “1” is continuous. A waveform WG on the lower side of FIG. 4 is a waveform of the reflected wave from the RFID tag 200. In this case, FIG. 4 illustrates an image representing an increase in frequency in each of the signals, in which a relationship between the frequency of the waveforms WA and the frequencies of the waveforms WF and WG does not appropriately represent an actual relationship between the frequencies.

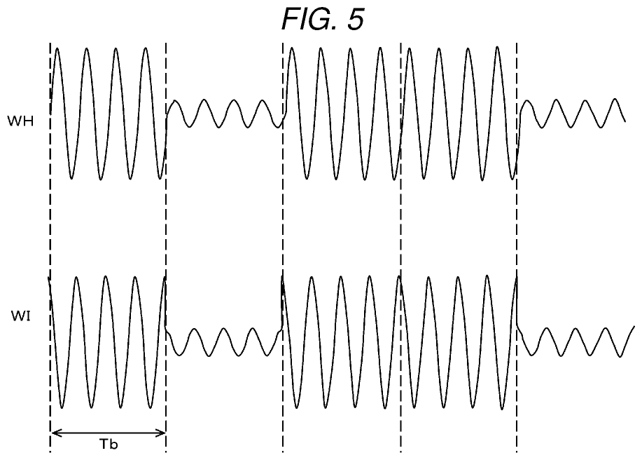

FIG. 5 is a diagram illustrating waveforms of the received I signal and the received Q signal detected by the quadrature detector 10.

If the received signal having the waveform WG on the lower side of FIG. 4 is detected by the quadrature detector 10 by quadrature detection, the received I signal having a waveform WH on the upper side of FIG. 5 and the received Q signal having a waveform WI on the lower side of FIG. 5 are obtained.

The frequencies of the received I signal and the received Q signal are f_{dev} and are higher than the cutoff frequency f_{cut} in the HPF 11. Therefore, the received I signal and the received Q signal can transmit through the HPF 11.

Accordingly, as in the embodiment, the transmitted data from the RFID tag 200 can be appropriately decoded.

While certain embodiments have been described, these embodiments have been presented by way of example only, and are not intended to limit the scope of the inventions. Indeed, the novel embodiments described herein may be embodied in a variety of other forms: furthermore various omissions, substitutions and changes in the form of the embodiments described herein maybe made without departing from the spirit of the inventions. The accompanying claims and their equivalents are intended to cover such embodiments or modifications as would fall within the scope and spirit of the invention.

What is claimed is:

1. A communication apparatus that communicates with a wireless tag, comprising:
a quadrature modulator configured to output a modulated wave obtained by performing quadrature modulation on a carrier wave using a first I signal and a first Q signal;
a transmission component configured to wirelessly transmit the modulated wave output from the quadrature modulator;
a reception component configured to receive a wireless signal obtained if the transmitted wave from the transmission component is backscattered by the wireless tag and undergoes amplitude shift keying;
a quadrature detector configured to detect the received signal received by the reception component using the carrier wave and to output a second I signal and a second Q signal;
a filter configured to block a frequency component lower than a cutoff frequency in the second I signal and the second Q signal;
an amplification component configured to amplify the second I signal and the second Q signal that are not blocked by the filter;
a detection component configured to detect at least one of the second I signal and the second Q signal that are amplified by the amplification component and to output a detection signal;
a decoding component configured to decode data transmitted from the wireless tag based on the detection signal output from the detection component; and
a generation component configured to generate the first I signal and the first Q signal such that the modulated wave is a signal obtained by shifting a frequency of the carrier wave by a frequency shift amount more than the cutoff frequency and to input the first I signal and the first Q signal to the quadrature modulator.

2. The communication apparatus according to claim 1,
wherein the generation component generates the first I signal and the first Q signal such that modulated data for shifting a frequency of the modulated wave output from the quadrature modulator are all 0's or all 1's.

3. The communication apparatus according to claim 1,
wherein the generation component generates the first I signal and the first Q signal such that modulated data for shifting a frequency of the modulated wave output from the quadrature modulator is data that changes between 0 and 1.

4. The communication apparatus according to claim 1,
wherein the quadrature modulator comprises a phase shifter, two mixers, and an adder.

5. The communication apparatus according to claim 1,
wherein the quadrature modulator comprises two mixers and an adder.

6. The communication apparatus according to claim 1,
wherein the filter is a SAW filter.

7. The communication apparatus according to claim 1,
wherein the generation component is a baseband processor.

8. The communication apparatus according to claim 1,
wherein the amplification component comprises two variable-gain amplifiers.

9. A communication method for communication with a wireless tag, comprising:
generating a first I signal and a first Q signal;
allowing a quadrature modulator to output a modulated wave obtained by performing quadrature modulation on a carrier wave using the first I signal and the first Q signal;
wirelessly transmitting the modulated wave;
receiving a wireless signal obtained if the wirelessly transmitted wave is backscattered by the wireless tag and undergoes amplitude shift keying;
detecting, by a quadrature detector, the received signal using the carrier wave and outputting a second I signal and a second Q signal;
blocking a frequency component lower than a cutoff frequency in the second I signal and the second Q signal by a filter;
amplifying the second I signal and the second Q signal that are not blocked by the filter;
detecting the second I signal and the second Q signal that are amplified and outputting a detection signal;
decoding data transmitted from the wireless tag based on the detection signal; and
generating each of the first I signal and the first Q signal as a signal that allows the modulated wave to be a signal obtained by shifting a frequency of the carrier wave by a frequency shift amount more than the cutoff frequency.

10. The communication method according to claim 9, further comprising:
generating the first I signal and the first Q signal such that modulated data for shifting a frequency of the modulated wave output from the quadrature modulator are all 0's or all 1's.

11. The communication method according to claim 9, further comprising:
generating the first I signal and the first Q signal such that modulated data for shifting a frequency of the modulated wave output from the quadrature modulator is data that changes between 0 and 1.

12. A reading apparatus that reads data stored in a radio frequency identification (RFID) tag, comprising:
a quadrature modulator configured to output a modulated wave obtained by performing quadrature modulation on a carrier wave using a first I signal and a first Q signal;
a transmission component configured to wirelessly transmit the modulated wave output from the quadrature modulator;
a reception component configured to receive a wireless signal obtained if the transmitted wave from the transmission component is backscattered by the wireless tag and undergoes amplitude shift keying;
a quadrature detector configured to detect the received signal received by the reception component using the carrier wave and to output a second I signal and a second Q signal;
a filter configured to block a frequency component lower than a cutoff frequency in the second I signal and the second Q signal;
an amplification component configured to amplify the second I signal and the second Q signal that are not blocked by the filter;
a detection component configured to detect at least one of the second I signal and the second Q signal that are amplified by the amplification component and to output a detection signal;
a decoding component configured to decode data transmitted from the wireless tag based on the detection signal output from the detection component; and
a generation component configured to generate the first I signal and the first Q signal such that the modulated wave is a signal obtained by shifting a frequency of the carrier wave by a frequency shift amount more than the cutoff frequency and to input the first I signal and the first Q signal to the quadrature modulator.

13. The reading apparatus according to claim 12,
wherein the generation component generates the first I signal and the first Q signal such that modulated data for shifting a frequency of the modulated wave output from the quadrature modulator are all 0's or all 1's.

14. The reading apparatus according to claim 12,
wherein the generation component generates the first I signal and the first Q signal such that modulated data for shifting a frequency of the modulated wave output from the quadrature modulator is data that changes between 0 and 1.

15. The reading apparatus according to claim 12,
wherein the quadrature modulator comprises a phase shifter, two mixers, and an adder.

16. The reading apparatus according to claim 12,
wherein the quadrature modulator comprises two mixers and an adder.

17. The reading apparatus according to claim 12,
wherein the filter is a SAW filter.

18. The reading apparatus according to claim 12,
wherein the generation component is a baseband processor.

19. The reading apparatus according to claim 12,
wherein the amplification component comprises two variable-gain amplifiers.
